(19) United States
(12) Patent Application Publication
(10) Pub. No.: US 2025/0056714 A1
(43) Pub. Date: Feb. 13, 2025

(54) PRINTED CIRCUIT BOARD WITH PASSIVE VIBRATION DAMPING

(71) Applicants: Continental Automotive Technologies GmbH, Hannover (DE); Continental Engineering Services GmbH, Frankfurt (DE)

(72) Inventors: Ralf Scheib, Wald-Michelbach (DE); Sven Schröder, Friedrichsdorf (DE); Markus Schnell, Echzell (DE); Stefan Kammann, Kelkheim (DE)

(73) Assignees: Continental Automotive Technologies GmbH, Hannover (DE); Continental Engineering Services GmbH, Frankfurt (DE)

(21) Appl. No.: 18/798,979

(22) Filed: Aug. 9, 2024

(30) Foreign Application Priority Data
Aug. 10, 2023 (DE) 10 2023 207 714.0

(51) Int. Cl. H05K 1/02; F16F 7/01; H05K 1/18; H05K 5/00

(52) U.S. Cl. CPC H05K 1/0271; F16F 7/015; H05K 1/181; H05K 5/0078; H05K 2201/10151; H05K 2201/2045

(57) ABSTRACT

A passive vibration damper for damping vibrations, particularly for damping vibrations of a printed circuit board, includes a chamber having a surrounding wall which defines a cavity. The volume of the cavity is at least 2% of the volume of the vibration absorber and not more than 95% of the volume of the vibration absorber. The chamber includes particles, wherein the wall and the particles have the same material composition.

### CROSS-REFERENCE TO RELATED APPLICATIONS

This application claims priority to German patent application No. 10 2023 207 714.0, filed Aug. 10, 2023, which is hereby incorporated by reference.

### TECHNICAL FIELD

The technical field relates in general to a passive vibration damper for damping vibrations, and more particularly for damping vibrations of a printed circuit board.

### BACKGROUND

Electronic devices or control units are often used in motor vehicles. These control units can be subjected to strong vibrations in operation if they are connected to moving or movable components, such as drive units. Shocks during driving can result in oscillations and therefore in vibrations. Vibrations, which can negatively affect the reliability of the devices in operation or also in the course of time, therefore represent a challenge for the reliability of such electronic devices.

Furthermore, vibrations can also sensitively interfere with or influence components on or in the electronic devices. For example, driving dynamics sensors, which can detect the acceleration or rotation of a motor vehicle or also a motorcycle, have thus proven to be very sensitive to vibrations. Vibrations or mechanical vibrations can be transmitted, for example, to printed circuit boards which carry these sensors. The functionality can be unfavorably influenced in this case and, for example, even make the measurements and the signals obtained therefrom unusable. In addition, the electronic components on the printed circuit board itself can also result in undesired vibrations.

Therefore, there are a variety of efforts to alleviate such vibrations. As an example, DE 10 2020 205 243 A1 of the applicant is cited here, which describes an electronic component having a vibration absorber for this purpose. The vibration damper or vibration absorber described here is produced from a composite material which contains particles embedded in a binder. The binder is an epoxy resin in this case.

The vibration absorber does offer good damping, but is rather light due to the selected materials, so that sufficient installation space has to be provided in order to achieve a corresponding mass.

Accordingly, a vibration absorber which does not have or at least mitigates the above-mentioned disadvantages would be desirable.

### SUMMARY

In a first aspect of the disclosure, a vibration absorber, in particular for the vibration damping of a printed circuit board, includes a chamber having a surrounding wall, which defines a cavity and may completely surround the cavity. The volume of the cavity is at least 2% of the volume of the vibration absorber. In one embodiment, the volume of the cavity may be at least 5% of the volume of the vibration absorber. In another embodiment, the volume of the cavity may be at least 10% of the volume of the vibration absorber. The volume of the cavity is not more than 95% of the volume of the vibration absorber. In one embodiment, the volume of the cavity is not more than 90% of the volume of the vibration absorber. In another embodiment, the volume of the cavity is not more than 80% or 70% of the volume of the vibration absorber. The chamber includes particles, wherein the wall and the particles have the same material composition.

An electronic device can therefore be provided, the electronic device having at least one printed circuit board which can be accommodated in a housing. The printed circuit board can include, in addition to other electronic components, at least one such vibration absorber. The electronic device may be for use in a motor vehicle and can represent, for example, a control unit for a braking system.

The disclosed vibration absorber can therefore be used in or on electronic devices, such as electronic control units for braking systems of a motor vehicle. When reference is made hereinafter to a motor vehicle for the sake of simplicity, a person skilled in the art understands that this is also to be understood to mean other driven vehicles, such as motorcycles or also rail vehicles.

Vibrations are viewed as mechanical vibrations in materials or bodies, which can themselves be elastic or can consist of elastically connected components. The vibrations can occur periodically or spontaneously in operation, for example when driving. Depending on the frequency range and duration of the vibration, the signal quality can be negatively affected upon the detection of the vehicle dynamics by means of corresponding sensors, such as inertial sensors or acceleration sensors, if these vibrations are transmitted to the sensors or to the underlying printed circuit board. If mechanical vibrations occur for a longer time, material fatigue can also occur.

Therefore, a vibration absorber directly at or on the printed circuit board of the electronic device is advantageously proposed in order to damp mechanical vibrations occurring in operation. The vibration absorber therefore enables mechanical vibrations which are transmitted in operation to the electronic device, in particular the printed circuit board, to be reduced. Electronic components which are arranged on the printed circuit board can also result in vibrations. The vibration absorber can therefore be arranged such that the vibrations originating from these components can be directly damped. Moreover, it can be particularly favorable if the vibration absorber is arranged as close as possible to the vibration-sensitive electronic parts or components, such as sensors.

In particular in motorcycles, for example, vibrations can occur with greater strength; moreover, installation space problems can be added here due to very limited space conditions. The batch sizes are also comparatively low.

Such damping masses or vibration absorbers are therefore often manufactured from metallic components and installed as a fixed metal block. For example, stamped parts made of copper or other metals which can be assembled to form the metal block are known. However, specified thicknesses or minimum thicknesses and dimensions of the stamped parts are disadvantageous here, which can be costly in particular in the case of installation space problems and small batch sizes, particularly because postprocessing efforts can also be added.

According to the disclosure, it can therefore be provided that the vibration absorber is not produced from prefinished metallic components, but rather from a metallic powder from which the vibration absorber can be produced by means of laser beam melting.

In such a powder-based method, the vibration absorber can be produced in a single manufacturing step. The selective laser beam melting can moreover offer the great advantage of leaving non-melted powder in the interior of the vibration absorber.

In this way, on the one hand, the damping properties can be improved and, on the other hand, manufacturing time can also be saved, since not all powder has to be melted. A vibration absorber can thus be provided by the laser beam melting which includes a chamber having a surrounding wall, which defines a cavity and preferably completely surrounds the cavity in this case. The laser beam melting, also known as the 3D printing method, is assumed to be fundamentally known and will therefore not be described in greater detail here.

The chamber may house non-melted particles or metallic grains. Accordingly, the wall and the particles can also have the same material composition.

If the vibration absorber is fastened directly on the printed circuit board or is connected thereto in a mechanically fixed manner, impacts or mechanical vibrations result in a vibration of the printed circuit board and thus of the vibration absorber, wherein kinetic energy can be absorbed from the vibrating printed circuit board by interactions of the particles with one another and/or of the particles with the surrounding wall. In this way, effective vibration damping of the printed circuit board can be achieved.

The vibration absorber according to the disclosure is therefore a passive damper and does not require a supply of energy. It can therefore be arranged very easily at various points on the printed circuit board, specifically both on the side of the printed circuit board on which the vibration-sensitive components are located and on the opposite side. A versatile usability of the vibration absorber according to the disclosure is thus provided.

The arrangement of the vibration absorber on the printed circuit board is therefore highly flexible, in particular because different geometric shapes of the vibration absorber can also be implemented very easily due to the production method.

The disclosure accordingly also includes a printed circuit board, for example, for a control unit of a braking system for a motor vehicle, having such a vibration absorber as described herein.

The printed circuit board may include vibration-sensitive components, such as specific sensors, for example, inertial sensors or acceleration sensors.

According to an advantageous design, the volume of the cavity of the vibration absorber can be at least 2%, preferably at least 5%, and particularly preferably at least 10% of the volume of the vibration absorber, so that sufficient space is available for the particles. Furthermore, the volume of the cavity can be not more than 95%, preferably not more than 90%, and particularly preferably not more than 80% or 70% of the volume of the vibration absorber, so that the surrounding wall can still be made sufficiently stable and rigid.

It is assumed that smaller particles can cause greater damping. Since the cohesion of the particles among one another, for example in the case of aluminum particles, can also have an influence on the damping properties, the particles also are not supposed to be excessively small. It is therefore considered to be advantageous if the particles of the vibration absorber have a mean grain size of at least 5 μm, preferably at least 10 μm, and particularly preferably at least 20 μm. Furthermore, it is considered to be favorable if the particles have a mean grain size of at most 200 μm, preferably at most 150 μm, and particularly preferably at most 100 μm.

Furthermore, it is assumed that round spherical particles can be better suitable for the damping. One embodiment therefore provides that the particles have a round, spherical, or rounded surface.

According to another embodiment, however, it can also be provided that the particles have an angular or edged surface. This can have the result that the particles interlock upon vibrations, due to which other excitation frequencies can be addressed.

It is assumed that the material of the particles itself has a rather minor effect on the damping, which enables particles to be selected which have good properties with respect to the laser beam welding. However, it is generally assumed that particles having a higher density have better damping than particles having lower density. Moreover, particles made of harder material or having harder surfaces may cause better damping.

A metallic alloy powder or metallic particles may therefore be selected for the particles, which have good properties with respect to the laser beam welding and are not excessively cost intensive. The particles may be produced on the basis of iron, copper, or aluminum, or can include corresponding alloys based on iron, copper, or aluminum. However, other materials can also be suitable, such as titanium alloys.

The vibration absorber and the chamber may have the same geometrical shape, which is advantageous since in this way a uniform wall thickness of the wall and homogeneous damping properties may be achieved. The vibration absorber can correspondingly be made stable and rigid in this way.

However, it is also possible to provide the chamber only in a specific area of the vibration absorber, for example, in a thickened area having an adjoining lateral projection for better fastening, in order to improve the fastening options with the printed circuit board. The chamber may accordingly also have a different geometric shape than the vibration absorber itself, for example, a round shape similar to a bubble.

The vibration absorber described herein may be adapted geometrically particularly easily to the respective conditions. Small cuboid vibration absorbers may thus be produced, for example, which may be attached flexibly in or on the printed circuit board. According to one embodiment, for example, cuboid vibration absorbers are provided, wherein the footprint is at most 20 mm*20 mm, preferably at most 15 mm*15 mm, and particularly preferably at most 10 mm*10 mm, and/or wherein the height is at most 10 mm, preferably at most 8 mm, and particularly preferably at most 5 mm. Very small vibration absorbers are therefore also possible.

It is obviously also possible to provide multiple such vibration absorbers, also of different sizes, also having different geometries, on one printed circuit board, also on both sides of the printed circuit board. It is apparent to a person skilled in the art that the geometries can be selected here according to the intended usage cases.

The vibration damping can take place particularly well if the largest surface of the vibration absorber is planar to the vibration plane of the element to be damped, in particular the printed circuit board, or the cause of the vibration.

The filling volume of the chamber, thus the volume component of the cavity which is filled with non-melted particles, can be set as needed during the production of the vibration absorber. Good damping properties can already be achieved if the chamber is filled by 30%, at least 40%, preferably at least 50%, particularly preferably by at least 60%, 70%, 80%, or even 90%, 95%, 98%, or 99% with particles. The degree of filling can be selected in dependence on the excitation frequencies to be damped and the particles. At lower frequencies, for example, below 1 kHz, lower degrees of filling can be favorable, at higher frequencies, for example, above 1 kHz, higher degrees of filling can be advantageous.

At lower excitation frequencies, it can therefore be advantageous if the chamber is not completely filled with particles. According to one embodiment, it is therefore provided that the chamber is not filled by at least 1% of the volume of the chamber, preferably at least 5% and particularly preferably at least 10% or even 20%.

The vibration absorber is advantageously designed according to one embodiment in order to damp excitation frequencies in a frequency range of 5 kHz to at least 200 kHz. According to a further embodiment, the vibration absorber is designed such that the vibration absorber can dampen excitation frequencies in a first frequency range below 100 kHz and/or in a second frequency range above 100 kHz. Particles of different sizes can also be combined with one another for this purpose.

In a further aspect, the disclosure also provides an electronic device, for example, an electronic control unit for a braking system of a motor vehicle or motorcycle, which includes at least one printed circuit board having at least one vibration absorber as described above.

### BRIEF DESCRIPTION OF THE DRAWINGS

Further details of the disclosure will become apparent from the description of the illustrated exemplary embodiments and the attached claims.

In the drawings:

FIG. 1 shows a diagonal view of a vibration absorber in an exemplary schematic form,

FIG. 2 shows a further diagonal view of the vibration absorber from FIG. 1 in a semitransparent view,

FIG. 3 shows a diagonal view of a vibration absorber according to one exemplary embodiment,

FIG. 4 shows a diagonal view of the vibration absorber in a sectional view according to one embodiment, and

FIG. 5 shows a top view of a schematically illustrated exemplary printed circuit board.

### DETAILED DESCRIPTION

In the following detailed description of various embodiments, for the sake of clarity, the same reference signs designate substantially identical parts in or on these embodiments. However, for better clarification, the embodiments illustrated in the figures are not always drawn to scale.

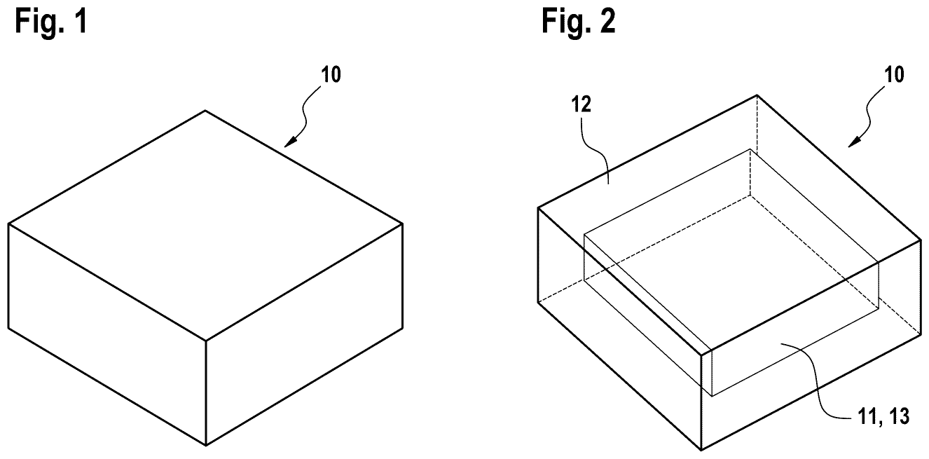

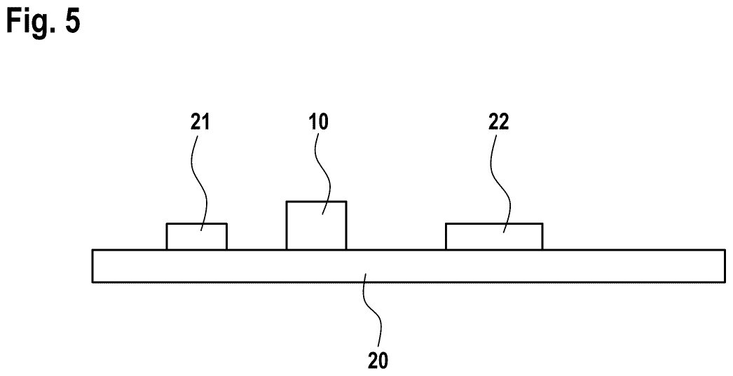

FIG. 1 shows a diagonal view of an exemplary vibration absorber 10 in schematic form, in particular for the vibration damping of a printed circuit board 20 as shown in FIG. 5. FIG. 2 shows a further diagonal view of the vibration absorber from FIG. 1 in a semitransparent view.

The vibration absorber 10 comprising a chamber 11 having a surrounding wall 12, which defines a cavity 13 and completely surrounds the cavity 13 in this case.

The volume of the chamber 11 is at least 2%, preferably at least 5%, and particularly preferably at least 10% of the volume of the vibration absorber 10. Furthermore, the volume of the chamber 11 is not more than 95%, preferably not more than 90%, and particularly preferably not more than 80% or 70% of the volume of the vibration absorber 10. In the present exemplary embodiment, the volume of the chamber 11 is approximately 40% of the volume of the vibration absorber 10.

The chamber 11 houses the particles 30. The wall 12 and the particles 30 have the same material composition here.

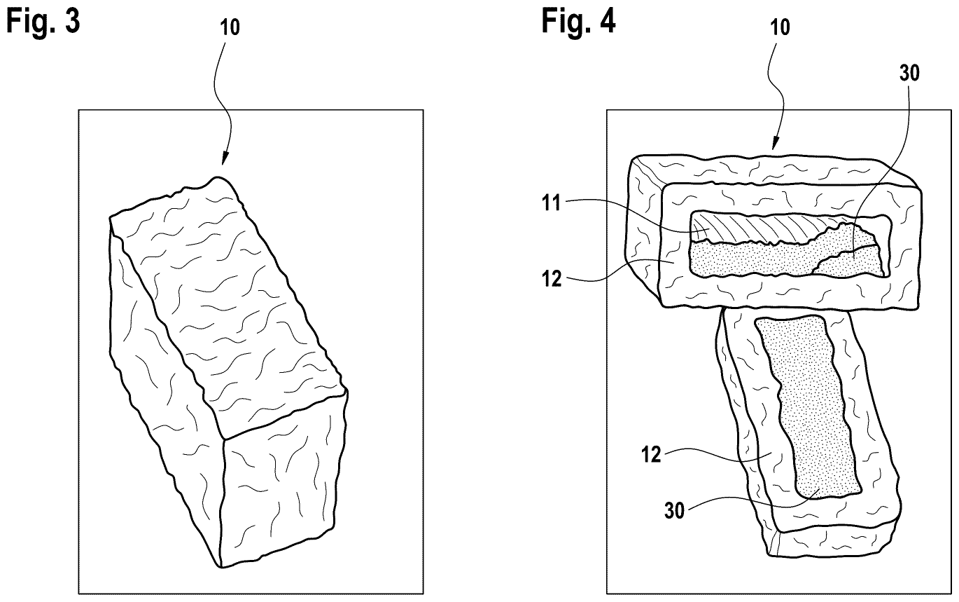

FIG. 3 shows a diagonal view of a vibration absorber according to one embodiment. FIG. 4 shows a further diagonal view of the vibration absorber in a sectional view. Particles are partially visible in the chamber 11.

FIG. 5 shows a top view of a schematically shown exemplary printed circuit board 20. The printed circuit board 20 includes a sensor 21, which is designed in the exemplary embodiment as an acceleration sensor, and a semiconductor module 22. It is apparent that this only represents exemplary equipment of a printed circuit board 20 for illustration. In the example of FIG. 5, the vibration absorber 10 is arranged on the same side of the printed circuit board 20 as the sensor 21 and the semiconductor module 22. It is also possible to arrange the vibration absorber 10 or an additional vibration absorber 10 on the side of the printed circuit board 20 opposite to the sensor 21.

According to one refinement, the vibration absorber 10 can also be geometrically shaped with regard to the intended use. Thus, for example, an L-shaped, a U-shaped, or even a circular ring-shaped or disk-shaped design of the vibration absorber 10 is also possible, in order to surround the sensor 21 on more than one side with the vibration absorber 10 and improve the damping in this way. Especially U-shaped or circular ring-shaped vibration absorbers 10, which can also be produced cost-effectively due to the production method, can surround the sensor 21 on multiple sides or even completely, which can have a very positive effect on the damping properties.

The vibration absorber 10 can be placed at a small distance to the sensor 21, which is also considered to be favorable for the damping. The contacting of the sensor 21 can take place from the opposite side of the printed circuit board here, so that the vibration absorber 10 can adjoin the sensor 21 quasi-directly.

An arrangement of the sensor 21 directly opposite on the side opposite to the sensor 21 can also be advantageous, since in this way a small distance to the sensor 21 can also be implemented. It is apparent to a person skilled in the art that the sensor 21 mentioned here is selected solely for simplification as an illustration and instead of the sensor 21, other vibration-sensitive parts or electronic components can also be understood here.

The particles 30 of the vibration absorber 10 have a mean grain size of at least 5 μm, preferably at least 10 μm, and particularly preferably at least 20 μm. Furthermore, the particles 30 have a mean grain size of at most 200 μm, preferably at most 150 μm, and particularly preferably at most 100 μm. In the example, the mean grain size of the particles is between 40 μm and 100 μm, for example, approximately 50 μm, 60 μm, 70 μm, or 80 μm.

Furthermore, the particles 30 have a round, spherical, or rounded surface.

In other embodiments, it can also be provided that the particles 30 have an angular or edged surface. Mixtures of various surfaces are also conceivable.

Furthermore, the particles include metallic alloy powder or metallic particles. These particles may be based on iron, copper, or aluminum or on alloys based on these materials. The example of FIG. 3 shows a vibration absorber 10 based on an aluminum alloy.

In the exemplary embodiment of FIG. 2, the vibration absorber 10 and the chamber 11 have the same geometric shape. However, the vibration absorber 10 and the chamber 11 may alternatively have different geometric shapes.

In the exemplary embodiment of FIG. 2 or 3, the vibration absorber 10 is formed cuboid, wherein the footprint is less than 20 mm*20 mm, preferably less than 15 mm*15 mm, and particularly preferably less than 10 mm*10 mm. Furthermore, the height of the vibration absorber 10 is at most 10 mm, preferably at most 8 mm, and particularly preferably at most 5 mm. Particularly small and compact vibration absorbers 10 can be produced according to the disclosure, having dimensions of, for example, 5 mm×10 mm×10 mm.

The chamber 11 is filled by at least 40%, preferably by at least 50%, particularly preferably by at least 60% with particles 30. Furthermore, the chamber 11 is not completely filled with particles 30, so that the particles can still move. According to one embodiment, at least 1% of the volume of the chamber 11 is not filled, preferably at least 5%, and particularly preferably at least 10% or even 20%. In the exemplary embodiment of FIG. 3, the chamber is filled by approximately 90% with particles 30.

The vibration absorber 10 described herein may dampen vibrations in a frequency range from 5 kHz to at least 200 kHz. Excitation frequencies can be in a first frequency range below 100 kHz and/or in a second frequency range above 100 kHz.

### LIST OF REFERENCE SIGNS

10 vibration absorber
11 chamber
12 wall
13 cavity
20 printed circuit board
21 acceleration sensor
22 IC
30 particles

1. A vibration absorber for vibration damping of a printed circuit board, comprising:
a chamber having a surrounding wall which defines a cavity;
wherein the volume of the cavity is at least 2% of the volume of the vibration absorber;
wherein the volume of the cavity is not more than 95% of the volume of the vibration absorber;
wherein the chamber houses particles; and
wherein the wall and the particles have the same material composition.

2. The vibration absorber as set forth in claim 1, wherein the surrounding wall completely surrounds the cavity.

3. The vibration absorber as set forth in claim 1, wherein the volume of the cavity is at least 5% of the volume of the vibration absorber.

4. The vibration absorber as set forth in claim 1, wherein the volume of the cavity is at least 10% of the volume of the vibration absorber.

5. The vibration absorber as set forth in claim 1, wherein the volume of the cavity is not more than 90% of the volume of the vibration absorber.

6. The vibration absorber as set forth in claim 1, wherein the volume of the cavity is not more than 70% of the volume of the vibration absorber.

6. The vibration absorber as set forth in claim 1, wherein the particles have a mean grain size of at least 5 μm.

7. The vibration absorber as set forth in claim 6, wherein the particles have a mean grain size of at most 200 μm.

8. The vibration absorber as set forth in claim 1, wherein the particles have a mean grain size between 20 μm and 100 μm.

9. The vibration absorber as set forth in claim 1, wherein the particles have a rounded surface.

10. The vibration absorber as set forth in claim 1, wherein the particles have an angular or edged surface.

11. The vibration absorber as set forth in claim 1, wherein the particles include metallic alloy powder and/or metallic particles.

12. A printed circuit board for a control unit of a braking system for a motor vehicle, comprising:
a vibration absorber having a chamber including a surrounding wall which completely surrounds a cavity, wherein the volume of the cavity is between 5% and 70% of the volume of the vibration absorber, wherein the chamber houses particles, and wherein the wall and the particles have the same material composition.

13. The printed circuit board as set forth in claim 12, wherein the vibration absorber and the chamber have the same geometric shape.

14. The printed circuit board as set forth in claim 13, further comprising at least one of a sensor.

15. The printed circuit board as set forth in claim 14, wherein the vibration absorber is arranged on the same side of the printed circuit board as the sensor.

16. The printed circuit board as set forth in claim 15, wherein the vibration sensor is disposed directly adjacent to the sensor.

17. The printed circuit board as set forth in claim 14, wherein the vibration absorber is arranged on the side of the printed circuit board opposite to the sensor.

18. The printed circuit board as set forth in claim 17, wherein the vibration absorber is disposed directly opposite to the sensor.

19. The printed circuit board as set forth in claim 12, wherein the vibration absorber is cuboid with a footprint at most 20 mm×20 mm and a height at most 10 mm.

20. The printed circuit board as set forth in claim 12, wherein the vibration absorber can damp vibrations in a frequency range from 5 kHz to at least 200 kHz, and/or wherein the vibration absorber can damp excitation frequencies in a first frequency range below 100 kHz and/or in a second frequency range above 100 kHz.
